(19) United States
(12) Patent Application Publication
(10) Pub. No.: US 2019/0243734 A1
(43) Pub. Date: Aug. 8, 2019

(54) MEMORY CONTROLLER AND OPERATING METHOD THEREOF

(71) Applicant: SK hynix Inc., Gyeonggi-do (KR)

(72) Inventor: Do Hyun KIM, Gyeonggi-do (KR)

(21) Appl. No.: 16/120,915

(22) Filed: Sep. 4, 2018

(30) Foreign Application Priority Data
Feb. 6, 2018 (KR) 10-2018-0014705

(51) Int. Cl. G06F 11/20; G11C 16/26; G06F 12/02; G06F 3/06

(52) U.S. Cl. CPC G06F 11/2094; G11C 16/26; G06F 12/0246; G06F 12/0253; G11C 11/5642; G06F 3/0647; G06F 3/0659; G06F 3/0679; G06F 3/0619

(57) ABSTRACT

A memory controller controls an operation of a semiconductor memory device including a plurality of memory cells in response to a request from a host. After a read operation of the semiconductor memory device succeeds, the memory controller determines whether a progressive failure of a selected memory block on which the read operation is to be performed has occurred.

### CROSS-REFERENCE TO RELATED APPLICATION

The present application claims priority under 35 U.S.C. § 119(a) to Korean patent application number 10-2018-0014705, filed on Feb. 6, 2018, which is incorporated herein by reference in its entirety.

### BACKGROUND

### Field of Invention

Various embodiments of the present disclosure generally relate to an electronic device. Particularly, the embodiments relate to a memory controller and an operating method thereof.

### Description of Related Art

Memory devices may be formed in a two-dimensional structure in which strings are arranged horizontally, or in a three-dimensional structure in which strings are arranged vertically. A three-dimensional semiconductor memory device was devised in order to overcome the degree of integration limit in two-dimensional semiconductor memory devices. A three-dimensional semiconductor memory device may include a plurality of memory cells vertically stacked on a semiconductor substrate. Operation of the memory device may be controlled by a memory controller in response to a request from a host.

### SUMMARY

Embodiments provide a memory controller having improved reliability and an operating method of the memory controller. According to an aspect of the present disclosure, there is provided a memory controller for controlling an operation of a semiconductor memory device including a plurality of memory cells in response to a request from a host. After a read operation of the semiconductor memory device succeeds, the memory controller determines whether a progressive failure of a selected memory block on which the read operation is to be performed has occurred.

The memory controller may determine whether the progressive failure of the selected memory block has occurred, based on a read voltage used in the read operation.

The memory controller may control an operation of the semiconductor memory device to perform a read retry operation. When a read voltage set used when the read retry operation succeeds corresponds to a critical read voltage, the memory controller may determine that the progressive failure of the selected memory block has occurred.

When the read voltage set used when the read retry operation succeeds corresponds to the critical read voltage, the memory controller may control the semiconductor memory device to move valid data stored in the selected memory block to another memory block.

The memory controller may determine the selected memory block as a victim block of garbage collection, and control the semiconductor memory device to move valid data stored in the selected memory block by the garbage collection to another memory block.

The memory controller may calculate an optimum read voltage by counting a number of memory cells for each threshold voltage range, and control the semiconductor memory device to perform a read operation, based on the calculated optimum read voltage. When the optimum read voltage corresponds to a critical read voltage, the memory controller may determine that the progressive failure of the selected memory block has occurred.

When the calculated optimum read voltage is within a range from the critical read voltage, the memory controller may determine that the progressive failure of the selected memory block has occurred.

According to an aspect of the present disclosure, there is provided a method for operating a memory controller for controlling a semiconductor memory device, the method including: receiving a read command from a host; controlling the semiconductor memory device to perform a read operation corresponding to the read command; and when the read operation corresponding to the read command succeeds, determining whether a progressive failure of a memory block corresponding to the read command has occurred, based on a read voltage used in the read operation.

The determining step may include: comparing the read voltage used in the read operation with a predetermined critical read voltage; and when the read voltage corresponds to the critical read voltage, determining that the progressive failure of the memory block has occurred.

The method may further include, when the read voltage corresponds to the critical read voltage, moving data stored in the memory block to another memory block.

The moving step may include: determining the memory block as a victim block; and controlling the semiconductor memory device to perform a garbage collection operation on the victim block.

In the controlling step, the semiconductor memory device may be controlled to perform a read operation, based on a read retry table.

The critical read voltage may include a read voltage corresponding to a last read retry step of the read retry table.

The controlling step may include: controlling the semiconductor memory device to sense threshold voltages of memory cells corresponding to a selected address, using a plurality of sensing voltages; detecting a number of memory cells having threshold voltages corresponding to a plurality of voltage ranges based on a result obtained by sensing the threshold voltages; determining, as a read voltage, a voltage in a voltage range having the smallest number of memory cells; and controlling the semiconductor memory device to perform a read operation, based on the determined read voltage.

In the comparing step, it may be determined whether the determined read voltage is within a predetermined range from the critical read voltage.

When the determined read voltage is within the predetermined range from the critical read voltage, it may be determined that the progressive failure of the memory block has occurred.

According to an aspect of the present disclosure, there is provided a memory system including a memory device and a controller. The memory device includes first and second memory blocks. The controller is configured to: control the memory device to perform a read operation to the first memory block by varying a read bias voltage with respect to an optimum read bias voltage; determine, when the read operation succeeds, the optimum read bias voltage to be a critical read bias voltage; and move data from the first memory block to the second memory block and blocking subsequent access to the first memory block according to the determining operation.

### BRIEF DESCRIPTION OF THE DRAWINGS

Various embodiments will now be described more fully with reference to the accompanying drawings; however, elements and features may be arranged or configured differently than shown or described herein. Thus, the present invention is not limited to the embodiments set forth herein. Rather, these embodiments are provided so that this disclosure is thorough and complete and fully conveys the scope of the embodiments to those skilled in the art.

In the drawings, dimensions of the figures may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating an example of a memory system.

FIG. 2 is a block diagram illustrating a memory controller of FIG. 1.

FIG. 3 is a block diagram illustrating a semiconductor memory device of FIG. 1.

FIG. 4 is a diagram illustrating an embodiment of a memory cell array of FIG. 3.

FIG. 5 is a circuit diagram illustrating any one memory block among memory blocks of FIG. 3.

FIG. 6 is a circuit diagram illustrating another embodiment of any one memory block among the memory blocks of FIG. 4.

FIG. 7 is a circuit diagram illustrating an embodiment of any one memory block among the plurality of memory blocks included in the memory cell array of FIG. 3.

FIG. 8 is a flowchart illustrating an operating method of the memory controller according to an embodiment of the present disclosure.

FIGS. 9A, 9B, and 9C are diagrams illustrating a read retry voltage.

FIG. 10 is a diagram illustrating an exemplary read retry table.

FIG. 11 is a flowchart illustrating an exemplary read retry method.

FIG. 12 is a flowchart illustrating a detailed configuration of determining occurrence of a progressive failure, which is an operation shown in FIG. 8.

FIG. 13 is a diagram illustrating another embodiment of operations of step S120 of FIG. 8.

FIG. 14 is a flowchart illustrating a read voltage determination method described with reference to FIG. 13.

FIG. 15 is a diagram illustrating determining whether an optimum read voltage calculated by an optimum voltage calculation method of FIGS. 13 and 14 corresponds to a critical voltage.

FIG. 16 is a block diagram illustrating another embodiment of the memory system of FIG. 1.

FIG. 17 is a block diagram illustrating an exemplary application of the memory system of FIG. 16.

FIG. 18 is a block diagram illustrating a computing system including the memory system described with reference to FIG. 17.

### DETAILED DESCRIPTION

In the following detailed description, embodiments of the present disclosure are shown and described, simply by way of example. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed. In addition, when an element is referred to as “including” a component, this indicates that the element may further include one or more other components rather than excluding such other component(s), unless the context indicates otherwise. Also, throughout the specification, reference to “an embodiment” or the like is not necessarily to only one embodiment, and different references to “an embodiment” or the like are not necessarily to the same embodiment(s).

Various embodiments of the present disclosure will be described in detail with reference to the accompanying drawings. The same reference numerals are used to designate the same elements as those shown in other drawings. In the following description, only portions necessary for understanding operations according to the embodiments may be described; description of known technical material may be omitted so as to not obscure important concepts of the embodiments.

FIG. 1 is a block diagram illustrating an example of a memory system.

Referring to FIG. 1, the memory system 1000 includes a semiconductor memory device 100 and a memory controller 1100.

The semiconductor memory device 100 operates under the control of the memory controller 1100. More specifically, the semiconductor memory device 100 writes data in a memory cell array in response to a write request from the memory controller 1100. When a write command, an address, and data are received as the write request from the memory controller 1100, the semiconductor memory device 100 writes data in memory cells indicated by the address.

The semiconductor memory device 100 performs a read operation in response to a read request from the memory controller 1100. When a read command and an address are received as the read request from the memory controller 1100, the semiconductor memory device 100 reads data of memory cells indicated by the address, and outputs the read data to the memory controller 1100.

The semiconductor memory device 100 may be a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or the like. Also, the semiconductor memory device 100 of the present disclosure may be implemented in a three-dimensional array structure. The present disclosure may be applied to not only a flash memory device in which a charge storage layer is configured with a Floating Gate (FG) but also a Charge Trap Flash (CTF) in which a charge storage layer is configured with an insulating layer.

The memory controller 1100 is coupled between the semiconductor memory device 100 and a host 300. The memory controller 1100 is configured to interface the host 300 and the semiconductor memory device 100. The memory controller 1100 may transmit a write request or a read request to the semiconductor memory device 100 under the control of the host 300.

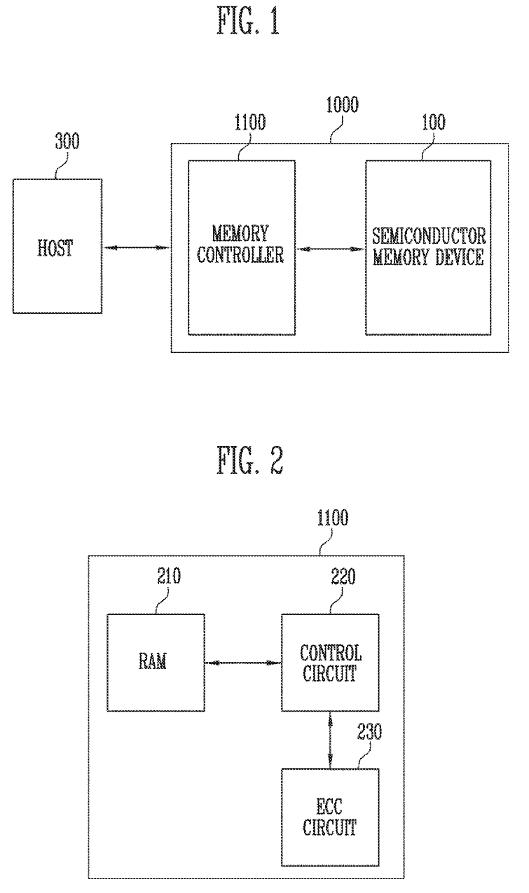

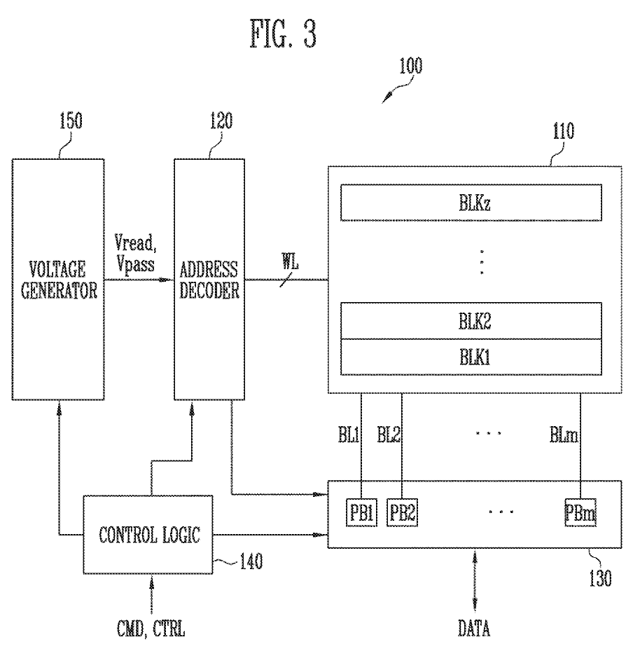

FIG. 2 is a block diagram illustrating a memory controller 1100 of FIG. 1.

Referring to FIG. 2, the memory controller 1100 includes a random access memory (RAM) 210, a control circuit 220, and an error correction code (ECC) circuit 230.

The RAM 210 operates under the control of the control circuit 220, and may be used as a work memory, a buffer memory, a cache memory or the like. When the RAM 210 is used as the work memory, the RAM 210 may temporarily store data processed by the control circuit 220. When the RAM 210 is used as the buffer memory, the RAM 210 may buffer data to be transmitted from a host (not shown) to the semiconductor memory device 100 or from the semiconductor memory device 100 to the host. When the RAM 210 is used as the cache memory, the RAM 210 may allow the semiconductor memory device 100 at a low speed to operate at a high speed.

The control circuit 220 is configured to control a read operation, a program operation, an erase operation, and a background operation of the semiconductor memory device 100. The control circuit 220 is configured to drive firmware for controlling the semiconductor memory device 100.

The control circuit 220 may translate a logical address provided by the host into a physical address through a flash translation layer (FTL) (not shown). Specifically, the FTL may receive a logical address, using a mapping table, and translate the logical address into a physical address. The logical address may be a logical block address, and the physical address may be a physical page number. Several address mapping methods of the FTL exist according to mapping units. A representative address mapping method includes a page mapping method, a block mapping method, and a hybrid mapping method.

The ECC circuit 230 generates a parity that is an ECC of data to be programmed. Also, the ECC circuit 230 may correct an error of sensed page data using a parity.

In various embodiments, the ECC circuit 230 may divide data to be programmed into a plurality of units (chunks) and generate a parity of each data unit. Alternatively, the ECC circuit 230 may generate a parity of all data to be programmed.

In a program operation, when the ECC circuit 230 generates write data to which a parity bit is added and transfers the write data to the control circuit 220, the control circuit 220 transfers a program command, the write data, and a physical address to the semiconductor memory device 100.

In a read operation, the semiconductor memory device 100 reads page data from a page having a selected physical address in response to a read command, and transmits the read page data to the memory controller 1100.

The ECC circuit 230 determines whether an error is included in the page data under the control of the control circuit 220. For example, the ECC circuit 230 corrects an error using a parity. The ECC circuit 230 may correct an error by using coded modulation including any of low density parity check (LDPC) code, Bose, Chaudhuri, and Hocquenghem (BCH) code, turbo code, Reed-Solomon code, convolution code, recursive systematic code (RSC), trellis-coded modulation (TCM), block coded modulation (BCM), Hamming code, and the like.

In general, the number of correctable error bits increases when the number of parity bits increases. Therefore, a large number of error bits may be corrected with respect to page data including a large number of parity bits. When the number of error bits in the page data exceeds a set number, decoding may fail. When the number of error bits in the page data is less than or equal to the set number, the decoding may succeed.

The success of the decoding represents that a corresponding read command has passed. The failure of the decoding represents that the corresponding read command has failed. When the decoding succeeds, the memory controller 1100 outputs error-corrected page data to the host.

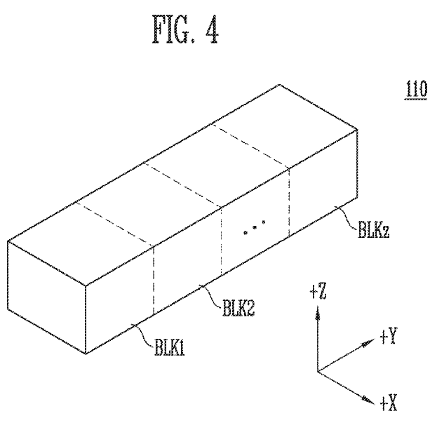

FIG. 3 is a block diagram illustrating an example of the semiconductor memory device of FIG. 1.

Referring to FIG. 3, the semiconductor memory device 100 includes a memory cell array 110, an address decoder 120, a read/write circuit 130, a control logic 140, and a voltage generator 150.

The memory cell array 110 includes a plurality of memory blocks BLK1 to BLKz. The plurality of memory blocks BLK1 to BLKz are coupled to the address decoder 120 through word lines WL. The plurality of memory blocks BLK1 to BLKz are coupled to the read/write circuit 130 through bit lines BL1 to BLm. Each of the plurality of memory blocks BLK1 to BLKz includes a plurality of memory cells. In an embodiment, the plurality of memory cells are nonvolatile memory cells, which may be configured with a vertical channel structure. The memory cell array 110 may be configured with a two-dimensional structure. In some embodiments, the memory cell array 110 may be configured with a three-dimensional structure. Each of the plurality of memory cells included in the memory cell array 110 may store data of at least one bit. In an embodiment, each of the plurality of memory cells may be a single-level cell (SLC) that stores data of one bit. In another embodiment, each of the plurality of memory cells may be a multi-level cell (MLC) that stores data of two bits. In still another embodiment, each of the plurality of memory cells may be a triple-level cell that stores data of three bits. In still another embodiment, each of the plurality of memory cells may be a quad-level cell that stores data of four bits. In some embodiments, the memory cell array 110 may include a plurality of memory cells that each stores data of five or more bits.

The address decoder 120, the read/write circuit 130, the control logic 140, and the voltage generator 150 operate as a peripheral circuit that drives the memory cell array 110. The address decoder 120 is coupled to the memory cell array 110 through the word lines WL. The address decoder 120 is configured to operate in response to the control of the control logic 140. The address decoder 120 receives an address through an input/output buffer (not shown) provided in the semiconductor memory device 100.

The address decoder 120 is configured to decode a block address in the received address. The address decoder 120 selects at least one memory block according to the decoded block address. In a read voltage application operation during a read operation, the address decoder 120 applies a read voltage Vread generated by the voltage generator 150 to a selected word line among the selected memory blocks, and applies a pass voltage Vpass to the other unselected word lines. In a program verify operation, the address decoder 120 applies a verify voltage generated by the voltage generator 150 to the selected word line among the selected memory blocks, and applies the pass voltage Vpass to the other unselected word lines.

The address decoder 120 is configured to decode a column address in the received address. The address decoder 120 transmits the decoded column address to the read/write circuit 130.

Read and program operations of the semiconductor memory device 100 are performed in units of pages. An address received in a request of the read operation and the program operation includes a block address, a row address, and a column address. The address decoder 120 selects one memory block and one word line according to the block address and the row address. The column address is decoded by the address decoder 120 to be provided to the read/write circuit 130.

The address decoder 120 may include a block decoder, a row decoder, a column decoder, an address buffer, and the like.

The read/write circuit 130 includes a plurality of page buffers PB1 to PBm. The read/write circuit 130 may operate as a “read circuit” in a read operation of the memory cell array 110, and operate as a “write circuit” in a write operation of the memory cell array 110. The plurality of page buffers PB1 to PBm are coupled to the memory cell array 110 through the bit lines BL1 to BLm. In order to sense threshold voltages of memory cells in the read operation and the program verify operation, the plurality of page buffers PB1 to PBm sense a change in amount of current flowing depending on a program state of a corresponding memory cell while continuously supplying sensing current to bit lines coupled to the memory cells, and latch the sensed change as sensing data. The read/write circuit 130 operates in response to page buffer control signals output from the control logic 140.

In the read operation, the read/write circuit 130 temporarily stores read data by sensing data of a memory cell and then outputs data DATA to the input/output buffer (not shown) of the semiconductor memory device 100. In an exemplary embodiment, the read/write circuit 130 may include a column selection circuit, and the like, in addition to the page buffers (or page registers).

The control logic 140 is coupled to the address decoder 120, the read/write circuit 130, and the voltage generator 150. The control logic 140 receives a command CMD and a control signal CTRL through the input/output buffer (not shown) of the semiconductor memory device 100. The control logic 140 is configured to control overall operations of the semiconductor memory device 100 in response to the control signal CTRL. Also, the control logic 140 outputs a control signal for controlling sensing node precharge potential levels of the plurality of page buffers PB1 to PBm. The control logic 140 may control the read/write circuit 130 to perform the read operation of the memory cell array 110.

In the read operation, the voltage generator 150 generates the read voltage Vread and the pass voltage Vpass in response to a control signal output from the control logic 140. In order to generate a plurality of voltages having various voltage levels, the voltage generator 150 may include a plurality of pumping capacitors for receiving an internal power voltage, and generate a plurality of voltages by selectively activating the plurality of pumping capacitors under the control of the control logic 140.

The address decoder 120, the read/write circuit 130, and the voltage generator 150 may serve as a “peripheral circuit” that performs a read operation, a write operation, and an erase operation on the memory cell array 110. The peripheral circuit performs the read operation, the write operation, and the erase operation on the memory cell array 110 under the control of the control logic 140.

FIG. 4 is a diagram illustrating an embodiment of the memory cell array of FIG. 3.

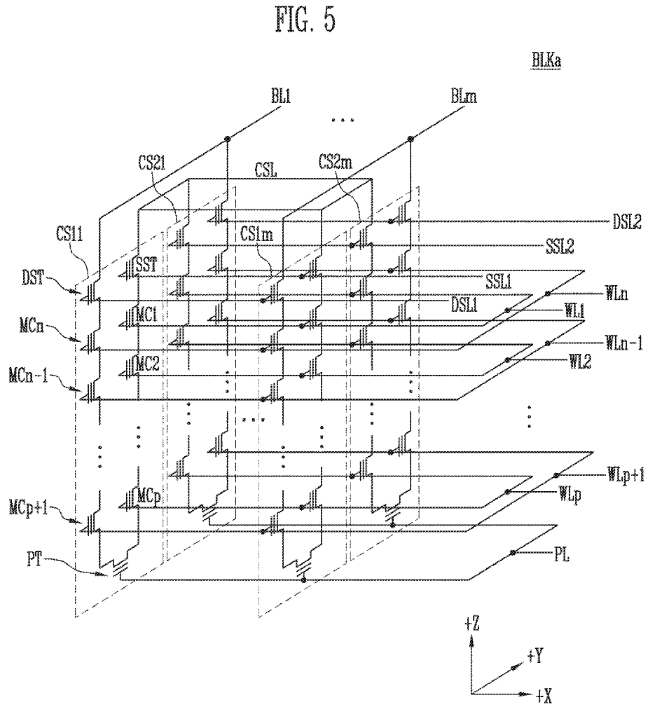

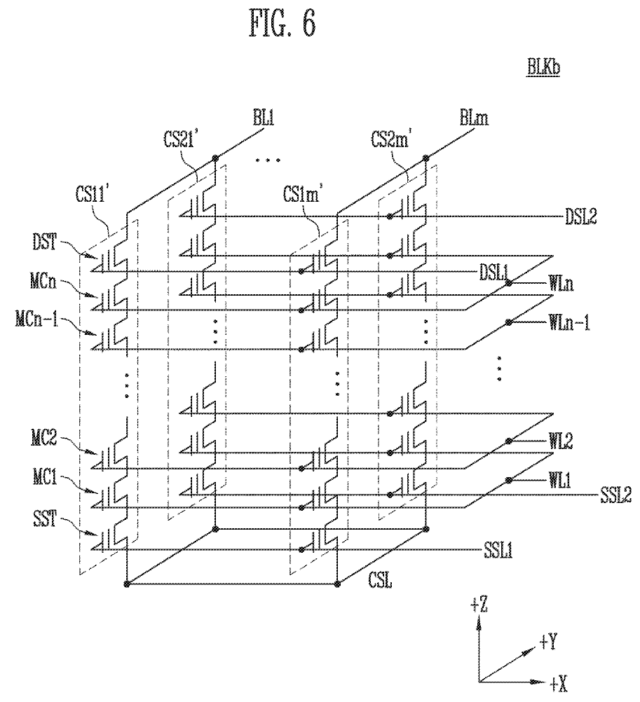

Referring to FIG. 4, the memory cell array 110 includes a plurality of memory blocks BLK1 to BLKz. Each memory block has a three-dimensional structure. Each memory block includes a plurality of memory cells stacked above a substrate. The plurality of memory cells are arranged along +X, +Y, and +Z directions. The structure of each memory block will be described in more detail with reference to FIGS. 5 and 6.

FIG. 5 is a circuit diagram illustrating any one memory block BLKa among the memory blocks BLK1 to BLKz of FIG. 3.

Referring to FIG. 5, the memory block BLKa includes a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings are arranged in a row direction (i.e., a +X direction). In FIG. 5, it is illustrated that two cell strings are arranged in a column direction (i.e., a +Y direction). However, this is for clarity of illustration; it will be understood that three cell strings may be arranged in the column direction.

Each of the plurality of cell strings CS11 to CS1m and CS21 to CS2m includes at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and memory cells MC1 to MCp.

In an embodiment, the source select transistors of cell strings arranged on the same row are coupled to a source select line extending in the row direction, and the source select transistors of cell strings arranged on different rows are coupled to different source select lines. In FIG. 5, the source select transistors of the cell strings CS11 to CS1m on a first row are coupled to a first source select line SSL1. The source select transistors of the cell strings CS21 to CS2m on a second row are coupled to a second source select line SSL2.

In another embodiment, the source select transistors of the cell strings CS11 to CS1m and CS21 to CS2m may be commonly coupled to one source select line.

The first to nth memory cells MC1 to MCn of each cell string are coupled between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp are sequentially arranged in the −Z direction, and are coupled in series between the source select transistor SST and the pipe transistor PT. The is (p+1)th to nth memory cells MCp+1 to MCn are sequentially arranged in the +Z direction, and are coupled in series between the pipe transistor PT and the drain select transistor DST. The first to pth memory cells MC1 to MCp and the (p+1)th to nth memory cells MCp+1 to MCn are coupled through the pipe transistor PT. Gate electrodes of the first to nth memory cells MC1 to MCn of each cell string are coupled to first to nth word lines WL1 to WLn, respectively.

A gate of the pipe transistor PT of each cell string is coupled to a pipe line PL.

The drain select ran o DST of each cell string is coupled between a corresponding bit line and the memory cells MCp+1 to MCn. Cell strings arranged in the row direction are coupled to a drain select line extending in the row direction. The drain select transistors of the cell strings CS11 to CS1m on the first row are coupled to a first drain select line DSL1. The drain select transistors of the cell strings CS21 to CS2m on the second row are coupled to a second drain select line DSL2.

Cell strings arranged in the column direction are coupled to a bit line extending in the column direction. In FIG. 5, the cell strings CS11 and CS21 on a first column are coupled to a first bit line BL1. The cell strings CS1m and CS2m on an mth column are coupled to an mth bit line BLm.

Memory cells coupled to the same word line in the cell strings arranged in the row direction constitute one page. For example, memory cells coupled to the first word line WL1 in the cell strings CS11 to CS1m on the first row constitute one page. Memory cells coupled to the first word line WL1 in the cell strings CS21 to CS2m on the second row constitute another page. As any one of the drain select lines DSL1 and DSL2 is selected, cell strings arranged in one row direction may be selected. As any one of the word lines WL1 to WLn is selected, one page may be selected in the selected cell strings.

In another embodiment, even bit lines and odd bit lines may be provided instead of the first to mth bit lines BL1 to BLm. In addition, even-numbered cell strings among the cell strings CS11 to CS1m or CS21 to CS2m arranged in the row direction may be coupled to the even bit lines, respectively, and odd-numbered cell strings among the cell strings CS11 to CS1m or CS21 to CS2m arranged in the row direction may be coupled to the odd bit lines, respectively.

In an embodiment, at least one of the first to nth memory cells MC1 to MCn may be used as a dummy memory cell. For example, the dummy memory cell(s) may be provided to decrease an electric field between the source select transistor SST and the memory cells MC1 to MCp. Alternatively, the dummy memory cell(s) may be provided to decrease an electric field between the drain select transistor DST and the memory cells MCp+1 to MCn. As a larger number of dummy memory cells are provided, the reliability of an operation of the memory block BLKa is improved. On the other hand, the size of the memory block BLKa is increased. As a smaller number of dummy memory cells are provided, the size of the memory block BLKa is decreased. On the other hand, the reliability of an operation of the memory block BLKa may be deteriorated.

In order to efficiently control the dummy memory cell(s), each may have a required threshold voltage. Before or after an erase operation of the memory block BLKa, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

FIG. 6 is a circuit diagram illustrating another embodiment BLKb of any one memory block among the memory blocks BLK1 to BLKz of FIG. 4.

Referring to FIG. 6, the memory block BLKb includes a plurality of cell strings CS11′ to CS1m′ and CS21′ to CS2m′. Each of the plurality of cell strings CS11′ to CS1m′ and CS21′ to CS2m′ extends along the +Z direction. Each of the plurality of cell strings CS11′ to CS1m′ and CS21′ to CS2m′ includes at least one source select transistor SST, first to nth memory cells MC1 to MCn, and at least one drain select transistor DST, which are stacked on a substrate (not shown) under the memory block BLKb.

The source select transistor SST of each cell string is coupled between a common source line CSL and the memory cells MC1 to MCn. The source select transistors of cell strings arranged on the same row are coupled to the same source select line. The source select transistors of the cell strings CS11′ to CS1m′ arranged on a first row are coupled to a first source select line SSL1. Source select transistors of the cell strings CS21′ to CS2m′ arranged on a second row are coupled to a second source select line SSL2. In another embodiment, the source select transistors of the cell strings CS11′ to CS1m′ and CS21′ to CS2m′ may be commonly coupled to one source select line.

The first to nth memory cells MC1 to MCn of each cell string are coupled in series between the source select transistor SST and the drain select transistor DST. Gate electrodes of the first to nth memory cells MC1 to MCn are coupled to first to nth word lines WL1 to WLn, respectively.

The drain select transistor DST of each cell string is coupled between a corresponding bit line and the memory cells MC1 to MCn. The drain select transistors of cell strings arranged in the row direction are coupled to a drain select line extending in the row direction. The drain select transistors of the cell strings CS11′ to CS1m′ on the first row are coupled to a first drain select line DSL1. The drain select transistors of the cell strings CS21′ to CS2m′ on the second row are coupled to a second drain select line DSL2.

Therefore, the memory block BLKb of FIG. 6 has a circuit similar to that of the memory block BLKa of FIG. 5. That is, the pipe transistor PT is excluded from each string in the memory block BLKb of FIG. 6.

In another embodiment, even bit lines and odd bit lines may be provided instead of the first to mth bit lines BL1 to BLm. In addition, even-numbered cell strings among the cell strings CS11′ to CS1m′ or CS21′ to CS2m′ arranged in the row direction may be coupled to the even bit lines, respectively, and odd-numbered cell strings among the cell strings CS11′ to CS1m′ or CS21′ to CS2m′ arranged in the row direction may be coupled to the odd bit lines, respectively.

In an embodiment, at least one of the first to nth memory cells MC1 to MCn may be used as a dummy memory cell. For example, the dummy memory cell(s) may be provided to decrease an electric field between the source select transistor SST and the memory cells MC1 to MCp. Alternatively, the dummy memory cell(s) may be provided to decrease an electric field between the drain select transistor DST and the memory cells MCp+1 to MCn. As a larger number of dummy memory cells are provided, the reliability of an operation of the memory block BLKb is improved. On the other hand, the size of the memory block BLKb is increased. As a smaller number of dummy memory cells are provided, the size of the memory block BLKb is decreased. On the other hand, the reliability of an operation of the memory block BLKb may be deteriorated.

In order to efficiently control the dummy memory cell(s), each may have a required threshold voltage. Before or after an erase operation of the memory block BLKb, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

FIG. 7 is a circuit diagram illustrating an embodiment of any one memory block BLKc among the plurality of memory blocks BLK1 to BLKz in the memory cell array 110 of FIG. 3.

Referring to FIG. 7, the memory block BLKc includes a plurality of strings CS1 to CSm. The plurality of strings CS1 to CSm may be coupled to a plurality of bit lines BL1 to BLm, respectively. Each of the plurality of strings CS1 to CSm includes at least one source select transistor SST, first to nth memory cells MC1 to MCn, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and the memory cells MC1 to MCn.

The first to nth memory cells MC1 to MCn of each cell string is coupled between the source select transistor SST and the drain select transistor DST.

The drain select transistor DST of each cell string is coupled between a corresponding bit line and the memory cells MC1 to MCn.

Memory cells coupled to the same word line constitute one page. As a drain select line DSL is selected, the cell strings CS1 to CSm may be selected. As any one of word lines WL1 to WLn is selected, one page among selected cell strings may be selected.

In another embodiment, even bit lines and odd bit lines may be provided instead of the first to mth bit lines BL1 to BLm. Even-numbered cell strings among the cell strings CS1 to CSm arranged may be coupled to the even bit lines, respectively, and odd-numbered cell strings among the cell strings CS1 to CSm may be coupled to the odd bit lines, respectively.

As shown in FIGS. 4 to 6, the memory cell array 110 of the semiconductor memory device 100 may be configured as having a three-dimensional structure. Alternatively, as shown in FIG. 7, the memory cell array 110 of the semiconductor memory device 100 may be configured as having a two-dimensional structure.

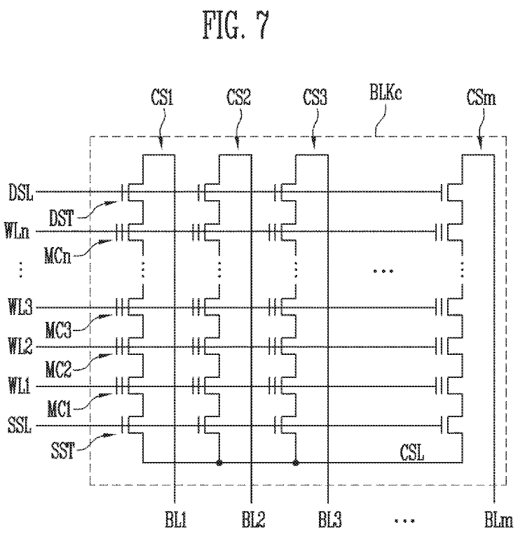

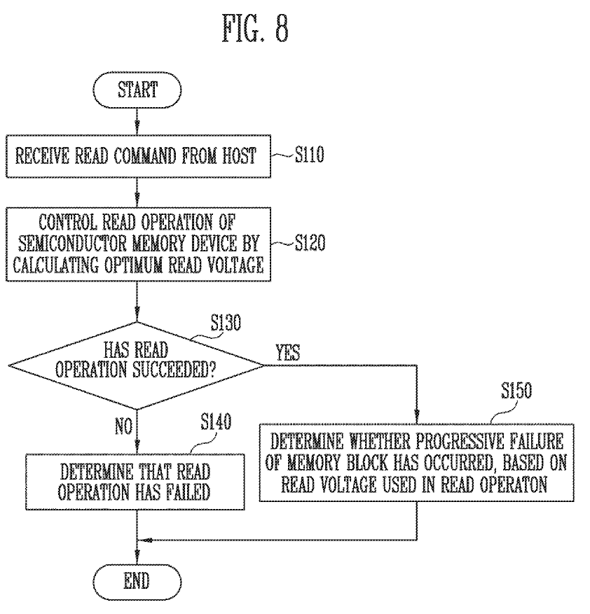

FIG. 8 is a flowchart illustrating an operating method of the memory controller 1100 according to an embodiment of the present disclosure.

Referring to FIG. 8, the operating method of the memory controller according to an embodiment of the present disclosure includes a step S110 of receiving a read command from the host 300, a step S120 of controlling a read operation of the semiconductor memory device 100 by calculating an optimum read voltage, a step S130 of determining whether the read operation has succeeded, a step S140 of determining that the read operation has failed when the read operation does not succeed, and a step S150 of determining whether a progressive failure of a memory block has occurred, based on a read voltage used in the read operation, when the read operation succeeds.

In the step S110, the memory controller 1100 receives a read command from the host 300. More specifically, the host 300 may transfer the read command together with a logical address of data, which is to be read, to the host 300.

In step S120, the memory controller 1100 may control a read operation of the semiconductor memory device 100 to perform the read operation in response to the read command. In this process, the memory controller 1100 may calculate an optimum read voltage and control the semiconductor memory device 100 to perform the read operation based on the calculated optimum read voltage.

The calculation of the optimum read voltage, which is performed in the step S120, may be performed using various methods. As an example, the memory controller 1100 may calculate the optimum read voltage while sequentially changing a read voltage with reference to a read retry table. As another example, the memory controller 1100 may sense threshold voltages of memory cells through a plurality of sensing voltages, and calculate the optimum read voltage, based on the number of memory cells having threshold voltages corresponding to a plurality of voltage ranges. Examples of a method for calculating the optimum read voltage in the step S120 will be described below with reference to the accompanying drawings.

From a result obtained by performing the step S120, in the step S130, it is determined whether the read operation of the semiconductor memory device 100 has succeeded or failed. When the read operation of the semiconductor memory device 100 does not finally succeed even though the read operation is performed by calculating the optimum read voltage (“NO” at step S130), it is determined that the read operation has failed at step S140. This may represent an uncorrectable error, e.g., Uncorrectable by Error Correction Code (UECC). Data corresponding to the read command from the host cannot be finally read.

When the read operation succeeds (“YES” at step S130), i.e., a successful result was obtained by performing the read operation by calculating the optimum read voltage at step S120, read data may be transferred to the host 300. When the read operation succeeds, it is determined whether a progressive failure of a memory block storing the read data has occurred based on the read voltage used in the read operation at step S150.

After a semiconductor memory device is completely manufactured, a test process is performed so as to check the manufacturing state, performance, and reliability of the semiconductor memory device. A memory block in which a failure occurs at an initial stage of the test process is determined as an initial bad block. Even when the semiconductor memory device passes through the test process, a defect or failure may occur when the semiconductor memory device is used in a subsequent process. The defect or failure occurring in the use of the semiconductor memory device is referred to as a progressive failure or progressive defect. The progressive failure may occur due to a defect caused in a manufacturing process of the semiconductor memory device, or due to repeated write/erase operations during operation of the semiconductor memory device. For example, as the write/erase operations are repeated, a threshold voltage distribution of the memory cells deteriorates, and it is difficult to read data. When data of some memory cells is erroneously read up to a certain degree, the data may be corrected by the ECC circuit 230. However, when the threshold voltage distribution of the memory cells has deteriorated to a degree where the data cannot be corrected even by the ECC circuit 230, a corresponding, read-target memory block cannot be used any more. Such memory block is determined as a memory block in which a progressive failure occurs.

In a typical case, when the read operation finally fails, a corresponding memory block is determined as a memory block in which a progressive failure occurs. The memory block in which it was determined that the progressive failure has occurred is no longer used. However, as the read operation fails, data stored in the corresponding memory block cannot be recovered due to the progressive failure in such block. As a result, reliable operation of the memory system cannot be ensured.

According to an embodiment of the present disclosure, when the read operation to a read-target memory block succeeds by calculating the optimum read voltage, it is determined whether the calculated optimum read voltage corresponds to a critical read voltage. When the calculated optimum read voltage corresponds to the critical read voltage, the lifespan of the read-target memory block is considered almost expired. Therefore, it is determined in advance that a progressive failure has occurred in the read-target memory block even when the current read operation to the read-target memory block succeeds. Therefore, data stored in the read-target memory block are moved to another memory block before the read fail due to the progressive failure actually occurs in the read-target memory block. Accordingly, the read-target memory block of which lifespan is considered almost expired is anticipatively determined as a memory block in which a progressive failure occurs, and data stored in the read-target memory block can be moved in advance to another memory block. Consequently, reliable operation of the memory system can be ensured.

A detailed configuration of the step S150 shown in FIG. 8 will be described below with reference to FIG. 12.

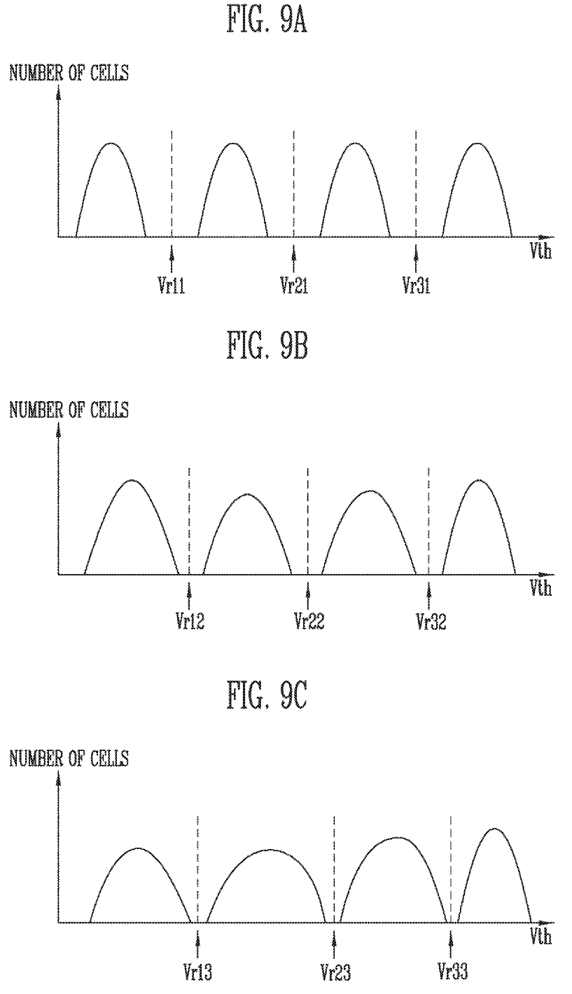

FIGS. 9A, 9B, and 9C are diagrams illustrating a read retry voltage.

Read retry refers to a method of repeating a read operation while changing a specific read voltage set, when the read operation is performed using the read voltage set. To this end, the memory controller 1100 refers to a read retry table. The read retry table may be initially stored in the memory cell array 110 of the semiconductor memory device 100. The read retry table stored in the memory cell array 110 may be loaded to the RAM 210 of the memory controller 1100 when the memory system 1000 is driven. The memory controller 1100 determines a read voltage to be used in the read operation, based on the read retry table loaded to the RAM 210. The determined read voltage, or information thereof, may be transferred to the semiconductor memory device 100 through a set parameter operation. The semiconductor memory device 100 stores the determined read voltage, or information thereof, transferred from the memory controller 11100 in a register, and such voltage or information is used in the read operation.

When data read as a result of the read operation is transferred to the memory controller 1100, an error of the data is corrected by the ECC circuit 230. When the error is corrected by the ECC circuit 230, the read operation succeeds, and the data of which error is corrected may be transferred from the memory controller 1100 to the host 300. When the error correction by the ECC circuit 230 fails, the memory controller 1100 changes the read voltage with reference to the read retry table. Therefore, the determined read voltage, or information thereof, stored in the register of the semiconductor memory device 100 may be changed through the set parameter operation. The semiconductor memory device 100 performs the read operation through the changed read voltage. Data read as a result of the read operation is transferred to the memory controller 1100 such that an error correction operation can be performed by the ECC circuit 230. By repeating the above-described processes, the read operation may be performed while changing the read voltage until the read operation succeeds.

Referring to FIG. 9A, there is illustrated a threshold voltage distribution of memory blocks on which a read operation is to be performed. In particular, a threshold voltage distribution of memory blocks of which statuses are satisfactory is illustrated in FIG. 9A. In the example of FIG. 9A, there is illustrated a threshold voltage distribution of a plurality of memory cells in the memory cell array, which are multi-level cells (MLCs), each storing data of two bits.

As shown in FIG. 9A, the read operation is performed through a first read voltage set Vr11, Vr21, and Vr31. Since the threshold voltage distribution of the memory blocks is satisfactory, the read operation succeeds using the first read voltage set Vr11, Vr21, and Vr3 shown in FIG. 9A.

Referring to FIG. 9B, there is illustrated a threshold voltage distribution of the memory blocks when a program/erase operation is repeatedly performed a certain number of times. For example, FIG. 9B may illustrate a threshold voltage distribution of the memory blocks, which is obtained by performing the program/erase operation 100 times. When the program/erase operation is repeatedly performed on the memory blocks, charge storage characteristics of memory cells are changed due to voltage stress. According to the threshold voltage distribution shown in FIG. 9B, error correction may fail when the read operation is performed through the first read voltage set Vr11, Vr21, and Vr31 applied in FIG. 9A. Thus, the read operation is performed through a second read voltage set Vr12, Vr22, and Vr32.

From the point of view of the memory controller 1100, in the read operation of the memory blocks according to the threshold voltage distribution shown in FIG. 9B, the memory controller 1100 may control the semiconductor memory device 100 to perform the read operation, using the first read voltage set Vr11, Vr21, and Vr31. When the error correction fails, as a result obtained by performing the read operation through the first read voltage set Vr11, Vr21, and Vr31, the memory controller 1100 may change the read voltage to the second read voltage set Vr12, Vr22, and Vr32 with reference to the read retry table. As a result obtained by performing the read operation through the second read voltage set Vr12, Vr22, and Vr32, the error correction succeeds, and the read operation finally succeeds.

Referring to FIG. 9C, there illustrated a threshold voltage distribution of the memory blocks when the program/erase operation is more repeatedly performed. For example, FIG. 9C may illustrate a threshold voltage distribution of the memory blocks when the program/erase operation is performed 500 times or so. According to the threshold voltage distribution shown in FIG. 9C, when the read operation is performed through the first read voltage set Vr11, Vr21, and Vr31 applied in FIG. 9A or the second read voltage set Vr12, Vr22, and Vr32 applied in FIG. 9B, the error correction may fail. Thus, the read operation performed through a third read voltage set Vr13, Vr23, and Vr33.

From the point of view of the memory controller 1100, in the read operation of the memory blocks according to the threshold voltage distribution shown in FIG. 9C, the memory controller 1100 may first control the semiconductor memory device 100 to perform the read operation, using the first read voltage set Vr11, Vr21, and Vr31. When the error correction fails, as a result obtained by performing the read operation through the first read voltage set Vr11, Vr21, and Vr31, the memory controller 1100 may change the read voltage to the second read voltage set Vr12, Vr22, and Vr32 with reference to the read retry table. When the error correction fails as a result obtained by performing the read operation through the second read voltage set Vr12, Vr22, and Vr32, the memory controller 1100 may change the read voltage to the third read voltage set Vr13, Vr23, and Vr33 with reference to the read retry table. As a result obtained by performing the read operation through the third read voltage set Vr13, Vr23, and Vr33, the error correction succeeds, and the read operation finally succeeds.

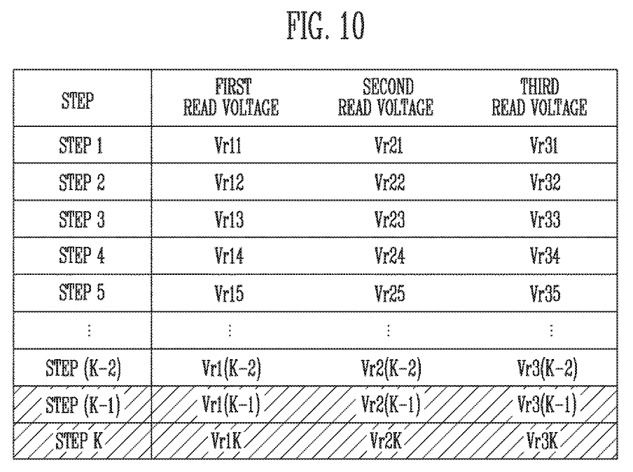

FIG. 10 is a diagram illustrating an exemplary read retry table.

Referring to FIG. 10, there are illustrated read voltage sets applied according to read retry steps. According to the embodiment of FIG. 10, read voltage sets used in a read operation on multi-level cells (MLCs) are illustrated. However, this is merely an example; a read retry table may be configured similarly to FIG. 10 with respect to single level cells (SLCs), triple level cells (TLCs), or memory cells storing data of other various bits.

In a first read retry step STEP 1, the semiconductor memory device 100 performs a read operation according to a first read voltage set Vr11, Vr21, and Vr31. More specifically, the memory controller 1100 controls an operation of the semiconductor memory device 100 to perform the read operation according to the first read voltage set Vr11, Vr21, and Vr31.

When error correction fails, as a result obtained by performing the read operation according to the first read voltage set Vr11, Vr21, and Vr31, the memory controller 1100 identifies with reference to the read retry table and transfers, to the semiconductor memory device 100, a second read voltage set Vr12, Vr22, and Vr32 applied in a second read retry step STEP 2.

When the error correction fails as a result obtained by performing the read operation according to the second read voltage set Vr12, Vr22, and Vr32, the memory controller 1100 identifies with reference to the read retry table and transfers, to the semiconductor memory device 100, a third read voltage set Vr13, Vr23, and Vr33 applied in a third read retry step STEP 3.

The above-described steps may be repeated until the error correction succeeds as a result obtained by performing the read operation according to a changed read voltage set. However, when the error correction fails even though the read operation is performed on all read retry steps defined by the read retry table, it may be determined that the read operation has failed.

The read retry table defined in FIG. 10 defines a Kth read retry step STEP K. When the error correction succeeds, as a result obtained by performing the read operation through the Kth read retry step STEP K, the lifespan of a read-target memory block is considered almost expired. This is because the error correction narrowly succeeds, as a result obtained by applying all K read retry steps defined by the read retry table. That is, when the error correction succeeds, as a result obtained by performing the read operation for a read-target memory block through the Kth read retry step STEP K, data stored in the read-target memory block may be at risk of read fail during a subsequent read operation even though the current read operation succeeds for the read-target memory block.

Therefore, when the error correction succeeds as a result obtained by performing the read operation for a read-target memory block through the Kth read retry step STEP K, it may be determined that a progressive failure of the read-target memory block has occurred.

That is, according to an embodiment of the present disclosure, in a read operation based on read retry, when a read voltage used in the read operation is a read voltage corresponding to the last step of the read retry table, it is determined in advance that a progressive failure of a read-target memory block has occurred, even when the current read operation to the read-target memory block succeeds, and data stored in the read-target memory block is moved to another memory block before the read fail due to the progressive failure actually occurs in the read-target memory block. Accordingly, the data stored in the read-target memory block can be protected. Consequently, the operation reliability of the memory system 1000 can be improved.

The above-described example illustrates that it is determined that a progressive failure of the read-target memory block has occurred only when the error correction succeeds as the result obtained by performing the read operation through the Kth read retry step STEP K. However, as shown in a shadowed portion of FIG. 10, it may be determined that a progressive failure of a read-target memory block has occurred even when the error correction succeeds as a result obtained by performing the read operation through a (K−1)th read retry step STEP (K−1) in addition to the Kth read retry step STEP K.

Although an embodiment in which it is determined that a progressive failure of a memory block has occurred with respect to only two read retry steps is illustrated in FIG. 10, it may be determined that a progressive failure of a memory block has occurred with respect to three or more read retry steps.

For example, it may be determined that a progressive failure of a memory block has occurred with respect to three read retry steps. When a read retry step through which the error correction succeeds belongs to any one of (K−2)th to Kth read retry steps STEP (K−2) to STEP K, it is determined that a progressive failure of a read-target memory block has occurred after the read operation succeeds, and data stored in the read-target memory block is moved to another memory block.

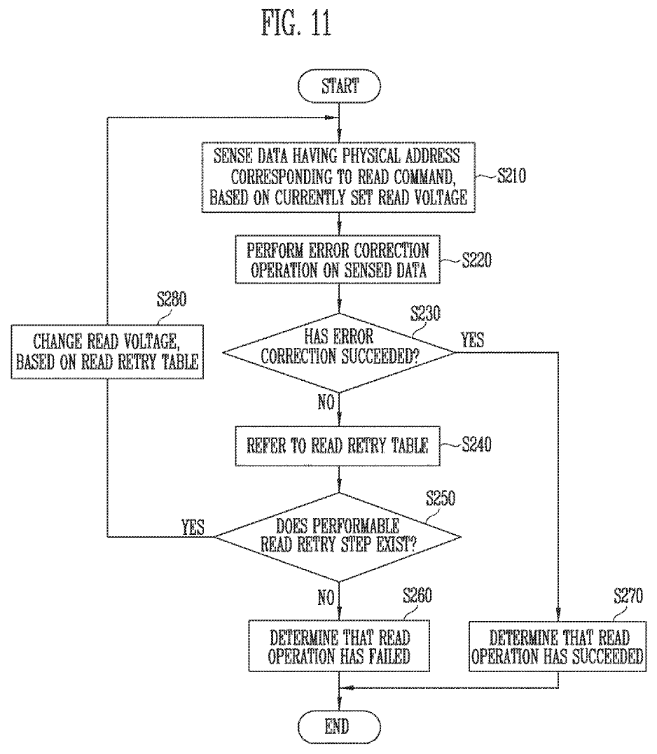

FIG. 11 is a flowchart illustrating an exemplary read retry method. An embodiment of step S120 shown in FIG. 8 is illustrated by the flowchart of FIG. 11.

In step S210, data having a physical address corresponding to a read command is sensed based on a currently set read voltage. For example, the data having the physical address corresponding to the read command is sensed based on the first read voltage set Vr11, Vr21, and Vr31 shown in FIG. 10.

The sensed data is transferred to the ECC circuit 230 of the memory controller 1100. An error correction operation on the sensed data is performed by the ECC circuit 230 at step S220. Subsequently, it is determined whether error correction has succeeded at step S230.

When the error correction succeeds (“YES” at step S230), it is determined that a read operation has finally succeeded at step S270, and the read operation according to read retry may be ended.

When the error correction fails (“NO” at step S230), the memory controller 1100 refers to the read retry table. First, it is determined whether a performable read retry step exists at step S250. Since the first read voltage set Vr11, Vr21, and Vr31 was used in the previous read operation (“NO” at step S250), the performable second read retry step STEP 2 exists (“YES” at step S250). A read voltage is changed based on the read retry table at step S280. Accordingly, the read voltage is changed to the second read voltage set Vr12, Vr22, and Vr32. Subsequently, the read operation and the error correction operation may be performed according to the changed read voltage. By repeating the above-described processing, read retry steps may be performed.

When no performable read retry step exists (“NO” at step S250), the read retry method proceeds to step S260. In the example of FIG. 10, when error correction fails with respect to data sensed through the Kth read voltage set Vr1K, Vr2K, and Vr3K according to the Kth read retry step STEP K, no performable read voltage exists. Therefore, it may be determined that the read operation has finally failed at the step S260.

FIG. 12 is a flowchart illustrating a detailed configuration of a step of determining occurrence of a progressive failure, which is shown in FIG. 8. An embodiment of the step S150 shown in FIG. 8 is illustrated in FIG. 12.

Referring to FIG. 12, in step S310, the calculated optimum read voltage (e.g., obtained in step S120 of FIG. 8) is compared with a predetermined critical read voltage. The critical read voltage may correspond to a threshold voltage distribution typically represented when the lifespan of a memory block is almost expired. For example, the critical read voltage may correspond to the Kth read voltage set Vr1K, Vr2K, and Vr3K or the (K−1)th read voltage set Vr1(K−1), Vr2(K−1), and Vr3(K−1) of FIG. 10.

In step S320, it is determined whether the optimum read voltage corresponds to the critical read voltage. For example, in FIG. 10, when the critical read voltage corresponds to the Kth read voltage set Vr1K, Vr2K, and Vr3K or the (K−1)th read voltage set Vr1(K−1), Vr2(K−1), and Vr3(K−1), the optimum read voltage may correspond to the critical read voltage. Since the read operation succeeds through the Kth or (k−1)th read retry step, it is determined in advance that a progressive failure of a read-target memory block has occurred.

When the optimum read voltage does not correspond to the critical read voltage (“NO” at step S320), it is determined that the progressive failure of the read-target memory block has not occurred, and hence the step S150 is ended.

When the optimum read voltage corresponds to the critical read voltage (“YES” at step S320), data stored in the read-target memory block on which the read operation is to be performed is moved to another memory block at step S330. The step S330 may be performed in various ways. As an example, the read-target memory block may be selected as a victim block of garbage collection. Accordingly, the garbage collection is performed, so that valid data of the read-target memory block can be moved to another memory block. As another example, the entire valid data of the read-target memory block may read by generating a read command, and the read data may be written in another memory block by generating a program command.

After the data stored in the read-target memory block is moved, it is determined that a progressive failure of the selected memory block has occurred at step S340. Due to the step S340, the read-target memory block may no longer be used later.

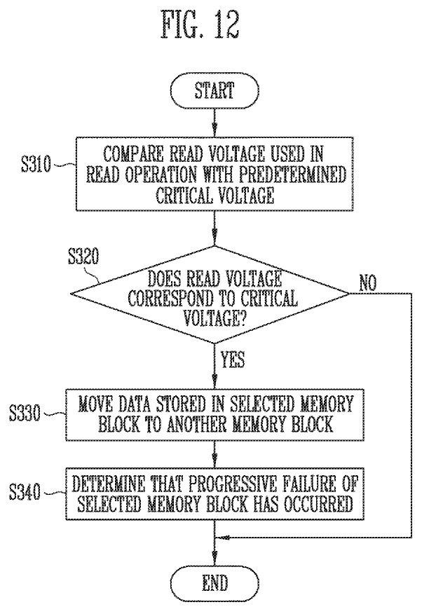

FIG. 13 is a diagram illustrating another embodiment of the step S120 of FIG. 8. As described above, the step S120 of FIG. 8 may be performed by the read retry method shown in FIG. 11. However, the step S120 of FIG. 8 may be performed by an optimum voltage calculation method shown in FIG. 13.

A plurality of voltages Vra, Vrb, Vrc, and Vrd may be sequentially used so as to determine an optimum read voltage between an ith program state Pi and an (i+1)th program state Pi+1. As the plurality of voltages Vra, Vrb, Vrc, and Vrd are applied, the number of memory cells existing in each threshold voltage range may be calculated.

For example, the number of memory cells of which threshold voltages belong to a range Vra to Vrb may be calculated by the following method. The number of memory cells that are turned off when the voltage Vra is applied thereto is equal to the number of memory cells distributed at the right side of the voltage Vra in FIG. 13, and the number of memory cells that are turned on when the voltage Vra is applied thereto is equal to the number of memory cells distributed at the left side of the voltage Vra in FIG. 13. In addition, the number of memory cells that are turned off when the voltage Vrb is applied thereto is equal to the number of memory cells distributed at the right side of the voltage Vrb in FIG. 13, and the number of memory cells that are turned on when the voltage Vrb is applied thereto is equal to the number of memory cells distributed at the left side of the voltage Vrb in FIG. 13.

Therefore, the number of memory cells in the range Vra to Vrb may be calculated by subtracting the number of memory cells that are turned off when the voltage Vrb is applied thereto from the number of memory cells that are turned off when the voltage Vra is applied thereto. Alternately, the same result may be obtained by subtracting the number of memory cells that are turned on when the voltage Vra is applied thereto from the number of memory cells that are turned on when the voltage Vrb is applied thereto.

In this manner, a range including the smallest number of memory cells is selected by calculating the number of memory cells in each of ranges Vra to Vrb, Vrb to Vrc, and Vrc to Vrd. In FIG. 13, the range Vrb to Vrc may be selected. An appropriate voltage in the selected range is determined as an optimum read voltage Vro. As an example, the optimum read voltage Vro may be determined as a median value of the range Vrb to Vrc. The optimum read voltage Vro may be determined as an average value of the voltages Vrb and Vrc.

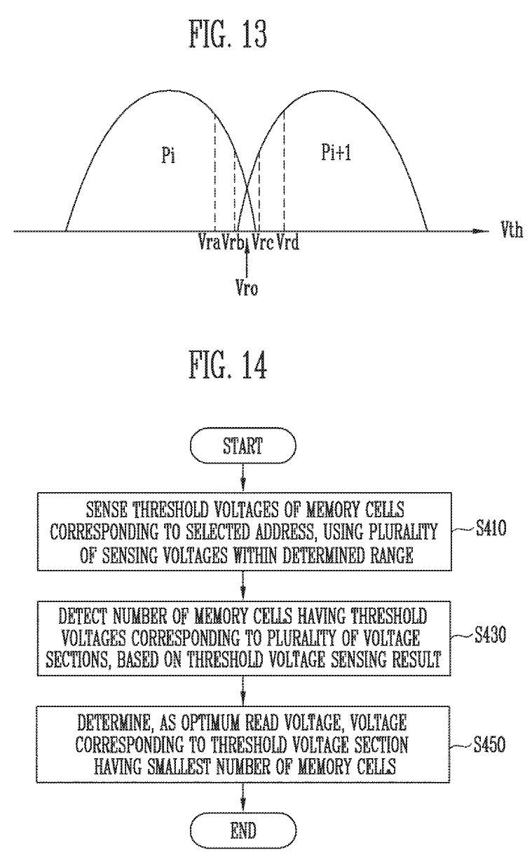

FIG. 14 is a flowchart illustrating a read voltage determination method described with reference to FIG. 13.

In step S410, threshold voltages of memory cells corresponding to a selected address are sensed using a plurality of sensing voltages within a determined range. As described with reference to FIG. 13, a plurality of voltage Vra, Vrb, Vrc, and Vrd are sequentially applied to selected memory cells to be read, and it is sensed whether the memory cells are turned on or turned off when each of the plurality of voltages Vra, Vrb, Vrc, and Vrd is applied.

Subsequently, in step S430, the number of memory cells having threshold voltages corresponding to each of a plurality of voltage ranges is detected based on a result obtained by sensing the threshold voltages. As described with reference to FIG. 13, the number of memory cells in each of the ranges Vra to Vrb, Vrb to Vrc, and Vrc to Vrd may be calculated.

Subsequently, in step S450, a voltage corresponding to the threshold voltage range having the smallest number of memory cells is determined as an optimum read voltage. In the step S450, a threshold voltage range having the smallest number of memory cells is determined. In the example of FIG. 13, the range Vrb to Vrc may be selected. Subsequently, an optimum read voltage in the range Vrb to Vrc is determined. As an example, a median value of the range Vrb to Vrc may be determined as the optimum read voltage Vro. The method for determining the optimum read voltage within the range Vrb to Vrc may be performed in various ways.

When the optimum read voltage Vro is determined, the read operation of the semiconductor memory device may be performed based on the determined optimum read voltage. Although a method for determining one read voltage among the plurality of optimum read voltages is illustrated in FIG. 13, other optimum read voltages may be determined in this manner. As an example, in the case of a read voltage for multi-level cells (MLCs), three read voltages may be determined by the method shown in FIG. 13. As another example, in the case of a read voltage for triple level cells (TLCs), seven read voltages may be determined by the method shown in FIG. 13.

As described above, according to an embodiment of the present disclosure, the step S120 of controlling the read operation of the semiconductor memory device by calculating the optimum read voltage shown in FIG. 8 may be performed using the read retry method described with reference to FIGS. 9A to 11, or may be performed using the optimum voltage calculation method described with reference to FIGS. 13 and 14.

FIG. 15 is a diagram illustrating a step of determining whether an optimum read voltage calculated by the optimum voltage calculation method of FIGS. 13 and 14 corresponds to the critical read voltage. More specifically, an example of the steps S310 and S320 of FIG. 12 is illustrated in FIG. 15.

When an optimum read voltage is determined as described with reference to FIGS. 13 and 14 (the step S120 of FIG. 8), and the read operation succeeds through the determined optimum read voltage (the step S130 of FIG. 8), it is to be determined whether a progressive failure of a read-target memory block has occurred, based on the optimum read voltage as described with reference to FIG. 12. To this end, the determined optimum read voltage is compared with the predetermined critical read voltage at step S310. In the above-described read retry method, the (K−1)th read voltage set Vr1(K−1), Vr2(K−1), and Vr3(K−1) or the Kth read voltage set Vr1K, Vr2K, and Vr3K, which is shown in FIG. 10, corresponds to the critical read voltage.

A critical read voltage Vcr according to the method for determining the optimum read voltage through FIGS. 13 and 14 may also be predetermined, e.g., experimentally determined. The critical read voltage Vcr may be predetermined as a voltage corresponding to a threshold voltage distribution of memory blocks which lifespan is almost expired. For example, the critical read voltage Vcr may be a voltage equal to any one of the Kth read voltage set Vr1k, Vr2K, and Vr3K.

When the optimum read voltage calculated as described with reference to FIGS. 13 and 14 exists within a range value Δd from the critical read voltage Vcr, it is determined that the optimum read voltage corresponds to the critical read voltage in the step S320 of FIG. 12. When the optimum read voltage calculated as described with reference to FIGS. 13 and 14 is out of the range value Ad from the critical read voltage Vcr, it is determined that the optimum read voltage does not correspond to the critical read voltage in the step S320 of FIG. 12.

As an example, in FIG. 15, when the optimum read voltage is calculated as a voltage Vro1, it is determined that the optimum read voltage Vro1 does not correspond to the critical read voltage Vcr. This is because a meaningful difference exists between the calculated optimum read voltage and the critical read voltage Vcr. Hence, it is determined that a progressive failure of a read-target memory block has not occurred.

As another example, in FIG. 15, when the optimum read voltage is calculated as a voltage Vro2, it is determined that Vro2 corresponds to the critical read voltage Vcr. This is because the calculated optimum read voltage and the critical read voltage Vcr exist within a similar range. Hence, data stored in the read-target memory block is moved to another memory block at step S330, and it is determined that a progressive failure of the read-target memory block has occurred at step S340.

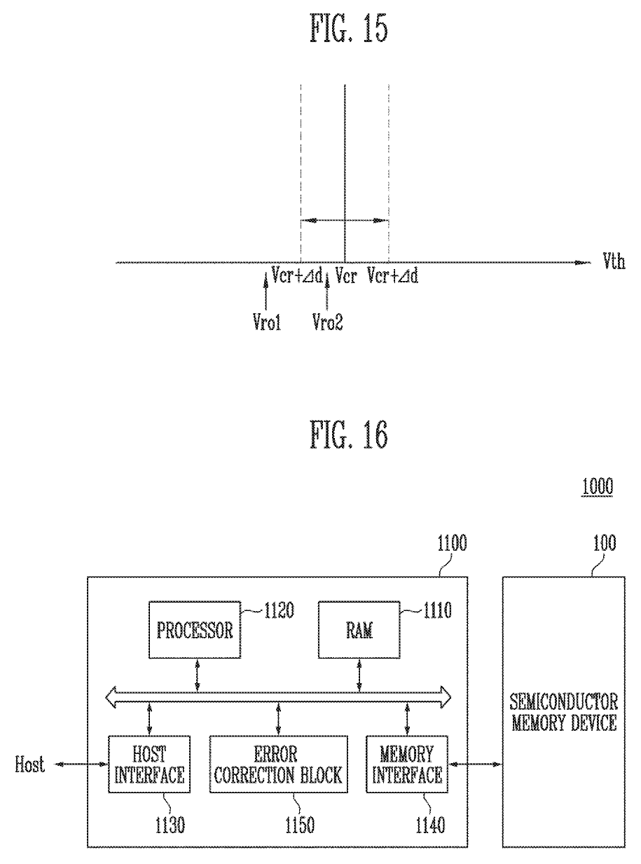

FIG. 16 is a block diagram illustrating another embodiment 1000 of the memory system of FIG. 1.

Referring to FIG. 16, the memory system 1000 includes a semiconductor memory device 100 and the memory controller 1100. The semiconductor memory device 100 may be the semiconductor memory device described with reference to FIGS. 1 and 3, and the memory controller 1100 may be the memory controller described with reference to FIGS. 1 and 2. Accordingly, overlapping description of these elements is omitted below.

The memory controller 1100 is coupled to a host (Host) and the semiconductor memory device 100. The memory controller 1100 corresponds to the memory controller 1100 of FIGS. 1 and 2. The memory controller 1100 is configured to access the semiconductor memory device 100 in response to a request from the host. For example, the memory controller 1100 is configured to control read, write, erase, and background operations of the semiconductor memory device 100. The memory controller 1100 is configured to provide an interface between the semiconductor memory device 100 and the host. The memory controller 1100 is configured to drive firmware for controlling the semiconductor memory device 100.

The memory controller 1100 includes a random access memory (RAM) 1110, a processor 1120, a host interface 1130, a memory interface 1140, and an error correction block 1150. The RAM 1110 may correspond to the RAM 210 of FIG. 2. The RAM 1110 is used as at least one of a working memory of the processor 1120, a cache memory between the semiconductor memory device 100 and the host, and a buffer memory between the semiconductor memory device 100 and the host. The processor 1120 controls overall operations of the memory controller 1100. The processing unit 1120 may correspond to the control circuit 220 of FIG. 2. Also, the memory controller 1100 may arbitrarily store program data provided from the host in a write operation.

The host interface 1130 includes a protocol for exchanging data between the host and the memory controller 1100. In an embodiment, the memory controller 1100 is configured to communicate with the host through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a private protocol.

The memory interface 1140 interfaces with the semiconductor memory device 100. For example, the memory interface 1140 may include a NAND interface or a NOR interface,

The error correction block 1150 is configured to detect and correct an error of data received from the semiconductor memory device 100 by using an error correction code (ECC). The processor 1120 may control the semiconductor memory device 100 to adjust a read voltage, based on an error detection result of the error correction block 1150, and to perform re-reading. In an embodiment, the error correction block 1150 may be provided as a component of the memory controller 1100. The error correction block 1150 may correspond to the ECC circuit 230 shown in FIG. 2.

The memory controller 1100 and the semiconductor memory device 100 may be integrated into a single semiconductor device. In an embodiment, the memory controller 1100 and the semiconductor memory device 100 may be so integrated to constitute a memory card such as a PC card (Personal Computer Memory Card International Association (PCMCIA)), a Compact Flash (CF) card, a Smart Media Card (SM or SMC), a memory stick, a Multi-Media Card (MMC, RS-MMC or MMCmicro), an SD Card (SD, miniSD, microSD or SDHC), or a Universal Flash Storage (UFS).

The memory controller 1100 and the semiconductor memory device 100 may be integrated into a single semiconductor device to constitute a semiconductor drive (solid state drive (SSD)), which includes a storage device configured to store data in a semiconductor memory. If the memory system 1000 is used as the semiconductor drive SSD, the operating speed of the host coupled to the memory system 1000 can be remarkably improved.

As another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multimedia Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an embodiment, the semiconductor memory device 100 or the memory system 1000 may be packaged in any of various forms such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi-Chip Package (MCP), Wafer-level Fabricated Package (WFP), or Wafer-level processed Stack Package (WSP).

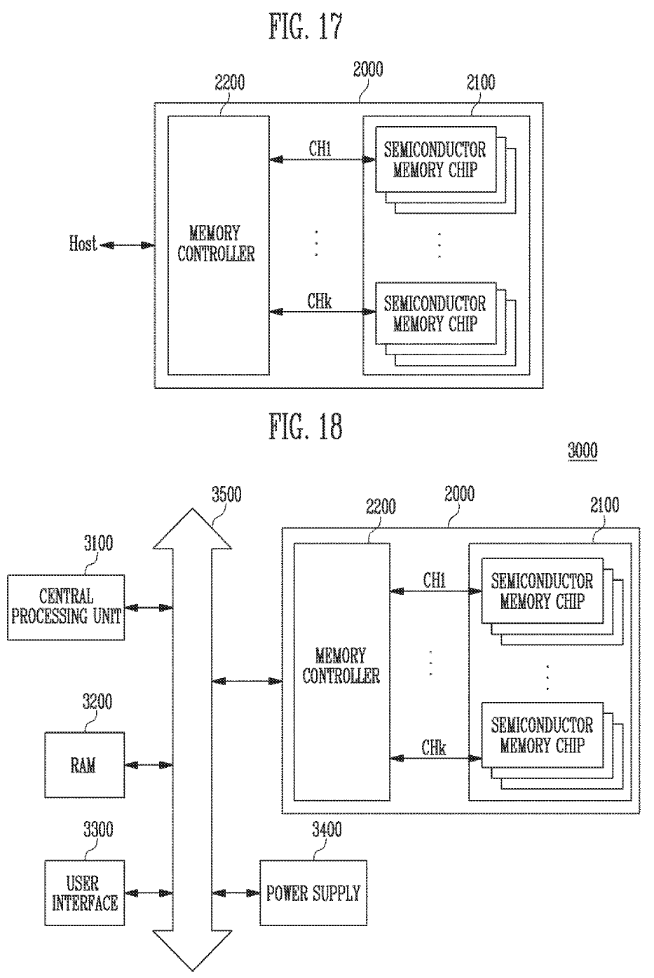

FIG. 17 is a block diagram illustrating an exemplary application of the memory system of FIG. 16.

Referring to FIG. 17, the memory system 2000 includes a semiconductor memory device 2100 and a memory controller 2200. The semiconductor memory device 2100 includes a plurality of semiconductor memory chips. The plurality of semiconductor memory chips are divided into a plurality of groups.

FIG. 17 illustrates that the plurality of groups communicate with the memory controller 2200 through first to kth channels CH1 to CHk. Each semiconductor memory chip may be configured and operated identically to the semiconductor memory device 100 described with reference to FIG. 3.

Each group is configured to communicate with the memory controller 2200 through one common channel. The memory controller 2200 is configured similarly to the memory controller 1100 described with reference to FIG. 16. The memory controller 2200 is configured to control the plurality of memory chips of the semiconductor memory device 2100 through the plurality of channels CH1 to CHk.

FIG. 18 is a block diagram illustrating a computing system including the memory system described with reference to FIG. 17.

Referring to FIG. 18, the computing system 300 includes a central processing unit (CPU) 3100, a RAM 3200, a user interface 3300, a power supply 3400, a system bus 3500, and a memory system 2000.

The memory system 2000 is electrically coupled to the CPU 3100, the RAM 3200, the user interface 3300, and the power supply 3400 through the system bus 3500. Data supplied through user interface 3300 or data processed by the CPU 3100 are stored in the memory system 2000.

FIG. 18 illustrates that the semiconductor memory device 2100 is coupled to the system bus 3500 through the memory controller 2200. However, the semiconductor memory device 2100 may be directly coupled to the system bus 3500. The function of the controller 2200 may be performed by the CPU 3100 and the RAM 3200.

FIG. 18 illustrates that the memory system 2000 described with reference to FIG. 17 is provided. However, the memory system 2000 may be replaced by the memory system 1000 described with reference to FIG. 16. In an embodiment, the computing system 3000 may be configured to include both of the memory systems 1000 and 2000 described with reference to FIGS. 16 and 17.

According to the present disclosure, a memory controller having improved reliability and an operating method of such a memory controller are provided.

Various embodiments have been disclosed herein, and although specific terms are employed, they are used and are to be interpreted in a generic and descriptive sense and not for purpose of limitation. In some instances, as would be apparent to one skilled in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory controller for controlling an operation of a semiconductor memory device including a plurality of memory cells in response to a request from a host,
wherein, after a read operation of the semiconductor memory device succeeds, the memory controller determines whether a progressive failure of a selected memory block on which the read operation is to be performed has occurred.

2. The memory controller of claim 1, wherein the memory controller determines whether the progressive failure of the selected memory block has occurred based on a read voltage used in the read operation.

3. The memory controller of claim 2, wherein the memory controller:
controls an operation of the semiconductor memory device to perform a read retry operation; and
when a read voltage set used when the read retry operation succeeds corresponds to a critical read voltage, determines that the progressive failure of the selected memory block has occurred.

4. The memory controller of claim 3, wherein, when the read voltage set used when the read retry operation succeeds corresponds to the critical read voltage, the memory controller controls the semiconductor memory device to move valid data stored in the selected memory block to another memory block.

5. The memory controller of claim 4, wherein the memory controller:
determines the selected memory block as a victim block of garbage collection; and
controls the semiconductor memory device to move valid data stored in the selected memory block by the garbage collection to another memory block.

6. The memory controller of claim 2, wherein the memory controller:
calculates an optimum read voltage by counting a number of memory cells for each threshold voltage range, and controls the semiconductor memory device to perform a read operation based on the calculated optimum read voltage; and
when the optimum read voltage corresponds to a critical read voltage, determines that the progressive failure of the selected memory block has occurred.

7. The memory controller of claim 6, wherein, when the calculated optimum read voltage is within a range from the critical read voltage, the memory controller determines that the progressive failure of the selected memory block has occurred.

8. A method for operating a memory controller for controlling a semiconductor memory device, the method comprising:
receiving a read command from a host;
controlling the semiconductor memory device to perform a read operation corresponding to the read command; and
when the read operation corresponding to the read command succeeds, determining whether a progressive failure of a memory block corresponding to the read command has occurred based on a read voltage used in the read operation.

9. The method of claim 8, wherein the determining step includes:
comparing the read voltage used in the read operation with a predetermined critical read voltage; and
when the read voltage corresponds to the critical read voltage, determining that the progressive failure of the memory block has occurred.

10. The method of claim 9, further comprising, when the read voltage corresponds to the critical read voltage, moving data stored in the memory block to another memory block.

11. The method of claim 10, wherein the moving step includes:
determining the memory block as a victim block; and
controlling the semiconductor memory device to perform a garbage collection operation on the victim block.

12. The method of claim 9, wherein, in the controlling step, the semiconductor memory device is controlled to perform a read operation based on a read retry table.

13. The method of claim 12, wherein the critical read voltage includes a read voltage corresponding to a last read retry step of the read retry table.

14. The method of claim 9, wherein the controlling step includes:
controlling the semiconductor memory device to sense threshold voltages of memory cells corresponding to a selected address using a plurality of sensing voltages;
detecting a number of memory cells having threshold voltages corresponding to a plurality of voltage ranges based on a result obtained by sensing the threshold voltages;
determining, as a read voltage, a voltage in a voltage range having the smallest number of memory cells; and
controlling the semiconductor memory device to perform a read operation based on the determined read voltage.

15. The method of claim 14, wherein, in the comparing step, it is determined whether the determined read voltage is within a predetermined range from the critical read voltage.

16. The method of claim 15, wherein, when the determined read voltage is within the predetermined range from the critical read voltage, it is determined that the progressive failure of the memory block has occurred.

17. A memory system comprising:
a memory device including first and second memory blocks; and
a controller configured to:
control the memory device to perform a read operation to the first memory block by varying a read bias voltage with respect to an optimum read bias voltage;
determine, when the read operation succeeds, the optimum read bias voltage to be a critical read bias voltage; and
move data from the first memory block to the second memory block and blocking subsequent access to the first memory block according to the determining operation.
